(19) United States
(12) Patent Application Publication
(10) Pub. No.: US 2025/0113661 A1
(43) Pub. Date: Apr. 3, 2025

(54) DISPLAY SUBSTRATE, METHOD FOR FORMING THE SAME, AND DISPLAY DEVICE

(71) Applicants: MIANYANG BOE OPTOELECTRONICS TECHNOLOGY CO., LTD., Mianyang, Sichuan (CN); BOE TECHNOLOGY GROUP CO., LTD., Beijing (CN)

(72) Inventors: Linchang Zhong, Beijing (CN); Wenhui Liu, Beijing (CN); Xiaolin Zhang, Beijing (CN)

(73) Assignees: MIANYANG BOE OPTOELECTRONICS TECHNOLOGY CO., LTD., Mianyang, Sichuan (CN); BOE TECHNOLOGY GROUP CO., LTD., Beijing (CN)

(21) Appl. No.: 18/290,912

(22) PCT Filed: Apr. 26, 2023
(86) PCT No.: PCT/CN2023/090957

§ 371 Date: Jan. 22, 2024

(51) Int. Cl. H10H 20/819

(52) U.S. Cl. CPC H10H 20/819

(57) ABSTRACT

A display substrate includes a base substrate including an aperture region, a transition region surrounding the aperture region and a display region surrounding the transition region, at least one annular isolation column structure located in the transition region, where the isolation column structure includes a plurality of isolation columns laminated sequentially in the direction away from the base substrate and an isolation layer located at one side of the isolation columns away from the base substrate, the isolation columns surrounding the aperture region, a recessed portion is formed in a side face of at least one isolation column, and a display layer covering the transition region and the display region, where the display layer includes a light-emitting layer, and the light-emitting layer is arranged in such a manner as to be interrupted by the recess of the isolation column.

### TECHNICAL FIELD

The present disclosure relates to the field of display technology, in particular to a display substrate, a method for forming the display substrate, and a display device.

### BACKGROUND

An Organic light-emitting diode (OLED) display device has become a next generation display technology with great development prospects due to such advantages as thin, light, wide viewing angle, active light emission, continuously adjustable emission color, low cost, fast response speed, low power consumption, low driving voltage, wide operating temperature range, simple production process, high light emission efficiency and flexible display.

With the increasing demand of users for products and the fierce competition environment in the industry, most mobile phone manufacturers are pursuing a higher screen-to-body ratio, so as to bring more conspicuous visual impact to users, thereby to win in a market competition. However, due to the presence of cameras and some sensors, it limits the development of the screen having a higher screen-to-body ratio, so placing the cameras and some sensors in the screen is highly concerned.

When some sensors such as a camera are placed in the screen, an opening needs to be made in the screen, but the opening in the screen tends to allow a common luminescent material layer to form an intrusion channel of moisture and oxygen. At present, it is mainly through the design of an isolation column to interrupt the common luminescent material layer, thereby to interrupt the intrusion channel of moisture and oxygen, and avoid the occurrence of packaging failure.

### SUMMARY

The technical problem to be solved by the present disclosure is to provide a display substrate, a method for forming the display substrate, and a display device, so as to improve the encapsulation reliability of the display substrate.

In order to solve the above technical problem, the embodiments of the present disclosure provide the following technical solutions.

In one aspect, a display substrate is provided, including:
a base substrate, including an aperture region, a transition region surrounding the aperture region, and a display region surrounding the transition region;
at least one annular isolation column structure located in the transition region, where the isolation column structure includes a plurality of isolation columns laminated sequentially in a direction away from the base substrate and an isolation layer located at one side of the isolation columns away from the base substrate, the isolation columns surround the aperture region, a recessed portion is formed in a side face of at least one isolation column, at least part of the isolation column is made of an insulating material, orthogonal projections of the isolation columns onto the base substrate are located within an orthogonal projection of the isolation layer onto the base substrate; and
a display layer, covering the transition region and the display region, where the display layer includes a light-emitting layer, and the light-emitting layer is arranged in such a manner as to be interrupted by the recessed portion of the isolation column.

In some embodiments, the isolation column includes: a first pattern and a second pattern laminated sequentially in the direction away from the base substrate, an outer edge of the second pattern extending beyond a side wall of the first pattern to form the recessed portion.

In some embodiments, the isolation column structure includes a first isolation column and a second isolation column laminated sequentially in the direction away from the base substrate, an orthogonal projection of the first isolation column onto the base substrate is located within an orthogonal projection of the second isolation column onto the base substrate, the first isolation column and the second isolation column each includes a first pattern and a second pattern laminated sequentially in the direction away from the base substrate, and an outer edge of the second pattern extends beyond a side wall of the first pattern to form the recessed portion.

In some embodiments, the first pattern is an inorganic insulation pattern, and the second pattern is a first metal pattern; or
the second pattern is an inorganic insulation pattern, and the first pattern is a first metal pattern.

In some embodiments, the display substrate at least includes a first buffer layer, a first gate insulating layer, a first gate metal layer, a second gate insulating layer, a second gate metal layer, an interlayer insulating layer, a second buffer layer and a second source/drain metal layer laminated one on another sequentially on the base substrate. The inorganic insulation pattern is arranged at a same layer and made of a same material as the second gate insulating layer, and the first metal pattern is arranged at a same layer and made of a same material as the first gate metal layer.

In some embodiments, the isolation layer includes an insulation pattern and/or a second metal pattern, and the isolation layer and the isolation column are made of different materials.

In some embodiments, the insulation pattern is arranged at a same layer and made of a same material as the second buffer layer, and the second metal pattern is arranged at a same layer and made of a same material as the second source/drain metal layer.

In some embodiments, the first gate insulating layer is located between the base substrate and the isolation columns, the display substrate includes at least two adjacent isolation columns in a direction parallel to the base substrate, an isolation groove structure is formed between the adjacent isolation columns, and the first gate insulating layer is exposed in the isolation groove structure.

In some embodiments, the first gate insulating layer and the second buffer layer are made of silicon oxide, the first buffer layer, the second gate insulating layer, and the interlayer insulating layer are made of silicon nitride, and the first gate metal layer and the second gate metal layer are made of Mo.

In some embodiments, the display substrate further includes: an isolation wall located in the transition region, a height of the isolation wall perpendicular to the base substrate being greater than a height of the isolation column structure perpendicular to the base substrate. The isolation column structure includes: at least one first annular isolation column structure located on one side of the isolation wall away from the aperture region, and at least one second annular isolation column structure located on one side of the isolation wall close to the aperture region.

In some embodiments, a height of the isolation column structure perpendicular to the base substrate ranges from 0.6 μm to 10 μm.

In some embodiments, the recessed portion has a width of 0.3 μm to 1.5 μm in a radial direction of the isolation column.

Embodiments of the present disclosure further provide a display device including the above-described display substrate.

The embodiments of the present disclosure further provide a method for forming a display substrate, including:
providing a base substrate, the base substrate including an aperture region, a transition region surrounding the aperture region, and a display region surrounding the transition region;
forming at least one annular isolation column structure in the transition region, where the isolation column structure includes a plurality of isolation columns laminated one on another sequentially in a direction away from the base substrate and an isolation layer located at one side of the isolation columns away from the base substrate, the isolation columns surround the aperture region, a recessed portion is formed in a side face of at least one isolation column, at least part of the isolation column is made of an insulating material, orthogonal projections of the isolation columns onto the base substrate are located within an orthogonal projection of the isolation layer onto the base substrate; and
forming a display layer in the transition region and the display region, where the display layer includes a light-emitting layer, and the light-emitting layer is arranged in such a manner as to be interrupted by the recessed portion of the isolation column.

In some embodiments, the display substrate includes a first film layer and a second film layer laminated sequentially in the direction away from the base substrate, and the forming the isolation columns includes: performing dry etching on the first film layer and the second film layer, to form a first pattern by using the first film layer, and form a second pattern by using the second film layer, an outer edge of the second pattern extending beyond a side wall of the first pattern to form the recessed portion.

Embodiments of the present disclosure have the following beneficial effects.

In the above-mentioned solutions, the isolation column structure includes a plurality of isolation columns laminated one on another sequentially in the direction away from the base substrate, so as to ensure a height of the isolation column structure, thereby to enable the light-emitting layer to be interrupted by the isolation column structure. The isolation column structure further includes an isolation layer, and the isolation layer and the isolation columns form an undercut structure, so as to further ensure that the light-emitting layer is interrupted by the isolation column structure. In addition, at least part of the isolation column is made of an insulating material, and the insulating material is non-conductive, so as to avoid conduction between the isolation columns and the light-emitting layer, thereby ensuring that the encapsulation at the isolation column structure does not fail, and improving the encapsulation reliability and product yield of the display substrate.

### BRIEF DESCRIPTION OF THE DRAWINGS

FIGS. 1 and 2 are each a schematic view showing a display substrate according to an embodiment of the present disclosure;

FIGS. 3-10 are schematic views showing forming a display substrate according to embodiments of the present disclosure;

FIG. 11 shows a schematic view showing a display substrate according to another embodiment of the present disclosure;

FIGS. 12-14 are sectional views of the display substrate according to another embodiment of the present disclosure.

### REFERENCE SIGN LIST

01 Base substrate
02 First buffer layer
03 First gate insulating layer
04 First gate metal layer
Second gate insulating layer
06 Second gate metal layer
07 Interlayer insulating layer
08 Second buffer layer
09 Second source/drain metal layer
10 Photoresist
13 Light-emitting layer
14 Cathode
15 Organic planarization layer
16 Encapsulation layer
21 First isolation column
22 Second isolation column
23 Pattern of interlayer insulating layer
24 Pattern of second gate metal layer
25 Pattern of first gate metal layer
26 Pattern of second gate insulating layer
27 Insulation pattern
28 Second metal pattern
011 Aperture region
012 Isolation column structure
013 Display region
014 Isolation wall

### DETAILED DESCRIPTION

In order to make the technical problems to be solved, the technical solutions and the advantages of the embodiments of the present disclosure more apparent, a detailed description will be given below with reference to the drawings and specific embodiments.

In the related art, an isolation column surrounding an aperture region is provided at the periphery of the aperture region by using a source/drain metal layer of a display substrate, the source/drain metal layer adopts a laminated structure of Ti/Al/Ti, and the source/drain metal layer in a transition region is etched so that an Al layer of the source/drain metal layer is indented with respect to a Ti layer, thereby forming the isolation column with a recessed portion at the side of the isolation column. However, the isolation column formed by using the source/drain metal layer is made of a conductive material, and a light-emitting layer of the display substrate is also made of a conductive material, therefore, in the transition region, there exists a conductive path formed by that the light-emitting layer is electrically connected to the isolation column. In the case where the display region is powered (energized), the light-emitting layer is negatively charged, so the conductive path formed by that the light-emitting layer is electrically connected to the isolation column in the transition region carries a negative voltage. When the display substrate is cut to form the aperture region, a chemical substance may enter the display substrate from a cutting edge, ions of the chemical substance and moisture may enter a region where the isolation column is located along a cross section of the light-emitting layer, and under the effect of an electric field and moisture, the chemical substance may react with an inorganic insulating material of the encapsulation layer. In this way, the inorganic insulating material corrodes and expands, and a failure occurs for the encapsulation layer, so the encapsulation reliability of the display substrate is relatively low. In addition, the source/drain metal layer has a relatively small thickness, so the isolation column formed by the source/drain metal layer has a relatively small height, and it is difficult to ensure that the light-emitting layer is interrupted by the isolation column.

Embodiments of the present disclosure provide a display substrate, a method for forming the display substrate, and a display device, so as to improve the encapsulation reliability of the display substrate.

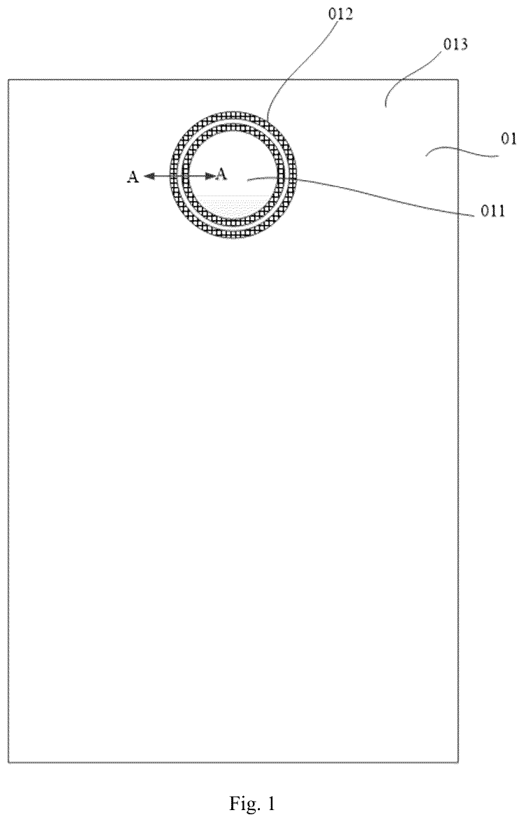

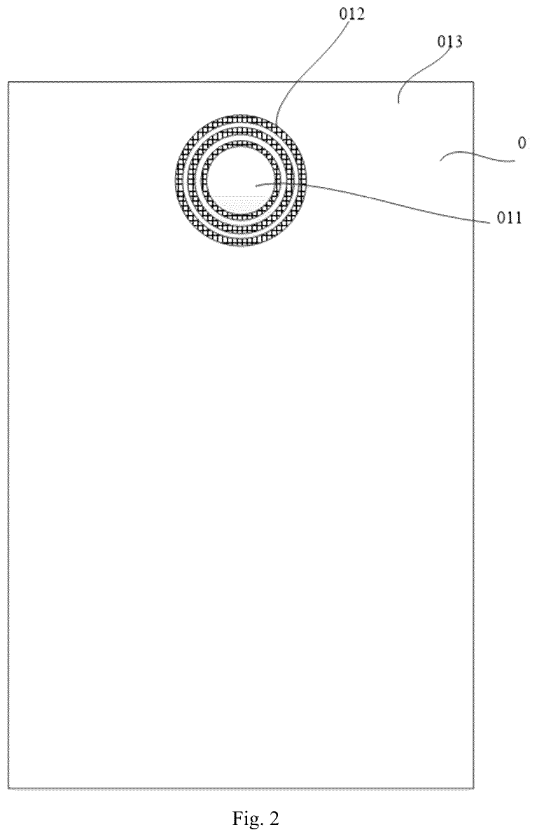

Embodiments of the present disclosure provide a display substrate, as shown in FIGS. 1 and 2, the display substrate includes a base substrate 01, the base substrate 01 includes an aperture region 011, a transition region surrounding the aperture region 011 and a display region 013 surrounding the transition region, and a light-emitting element for display is arranged in the display region 013. A camera and some sensors may be arranged in the aperture region 011. The transition region is located between the aperture region 011 and the display region 013.

The display substrate further includes at least one annular isolation column structure 012 located in the transition region, the isolation column structure 012 includes a plurality of isolation columns laminated one on another sequentially in a direction away from the base substrate 01 and an isolation layer located at one side of the isolation columns away from the base substrate, the isolation columns surround the aperture region 011, a recessed portion is formed in a side face of the isolation columns, at least part of the isolation columns is made of an insulating material, and orthogonal projections of the isolation columns onto the base substrate are located within an orthogonal projection of the isolation layer onto the base substrate.

The display substrate further includes a display layer covering the transition region and the display region 013, the display layer includes a light-emitting layer, and the light-emitting layer is arranged in such a manner as to be interrupted by the recessed portion of the isolation column.

In the related art, a single-layer isolation column is provided and surrounds the aperture region, and a height of the isolation column is limited. In the embodiments of the present disclosure, the isolation column structure includes a plurality of isolation columns laminated one on another sequentially in the direction away from the base substrate, so as to ensure a height of the isolation column structure, thereby to enable the light-emitting layer to be interrupted by the isolation column structure. The isolation column structure further includes an isolation layer, and the isolation layer and the isolation columns form an undercut structure, so as to further ensure that the light-emitting layer is interrupted by the isolation column structure. In addition, at least part of the isolation column is made of an insulating material, and the insulating material is non-conductive, so as to avoid conduction between the isolation columns and the light-emitting layer, thereby ensuring that the encapsulation at the isolation column structure does not fail, and improving the encapsulation reliability and product yield of the display substrate.

One annular isolation column structure 012 may be provided in the transition region, alternatively, two or more annular isolation column structures 012 may be provided. As shown in FIG. 1, in a specific example, two annular isolation column structures 012 are provided in the transition region. As shown in FIG. 2, in another specific example, three annular isolation column structures 012 are provided in the transition region. When multiple annular isolation column structures 012 are provided, it facilitates improving the encapsulation effect of the display substrate.

In some embodiments, the isolation column includes: a first pattern and a second pattern laminated sequentially in the direction away from the base substrate, an outer edge of the second pattern extending beyond a side wall of the first pattern to form the recessed portion.

The first pattern is an inorganic insulation pattern, and the second pattern is a first metal pattern. Alternatively, the second pattern is an inorganic insulation pattern, and the first pattern is a first metal pattern. In this way, it is able to avoid the conducting between the isolation columns and the light-emitting layer through the inorganic insulation pattern, so as to ensure that the encapsulation at the isolation column structure does not fail, and improve the encapsulation reliability and product yield of the display substrate. In addition, the isolation column formed by the first metal pattern and the inorganic insulation pattern has a sufficient height to ensure that the light-emitting layer is interrupted by the isolation column.

In some embodiments, the isolation column structure includes a first isolation column and a second isolation column laminated sequentially in the direction away from the base substrate, an orthogonal projection of the first isolation column onto the base substrate is located within an orthogonal projection of the second isolation column onto the base substrate, the first isolation column and the second isolation column each includes a first pattern and a second pattern laminated sequentially in the direction away from the base substrate, and an outer edge of the second pattern extends beyond a side wall of the first pattern to form the recessed portion. In this way, an undercut structure can be formed by the first isolation column and the second isolation column, ensuring that the light-emitting layer is interrupted by the isolation column structure. That the isolation column structure includes only two isolation columns is not limited in this embodiment, and the isolation column structure may further include more isolation columns arranged in a laminated manner, so as to provide a higher isolation column structure, thereby ensuring that the light-emitting layer is interrupted by the isolation column structure.

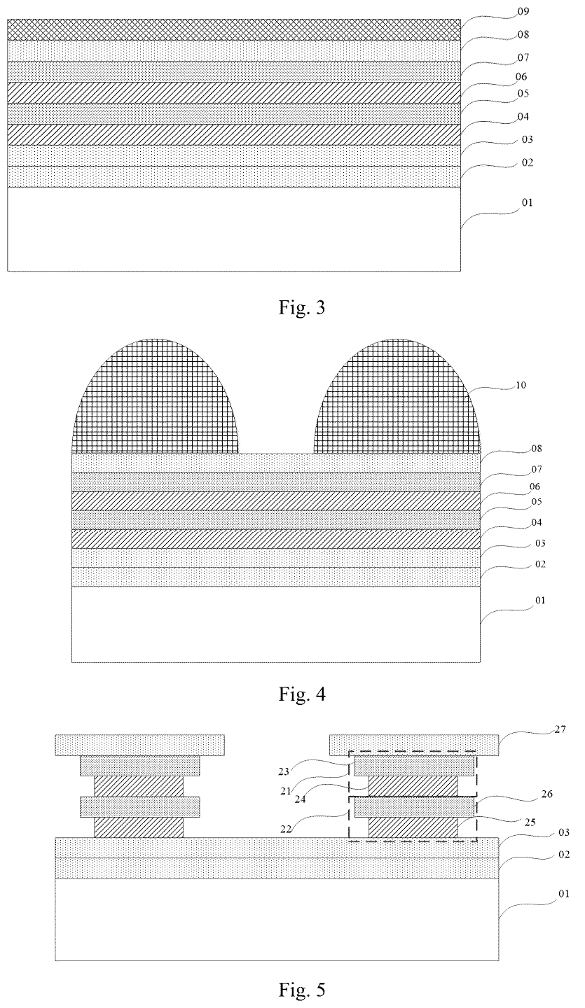

FIGS. 3-10 are sectional views of the display substrate in FIG. 1 along line AA. As shown in FIG. 3, the display substrate includes a first buffer layer 02, a first gate insulating layer 03, a first gate metal layer 04, a second gate insulating layer 05, a second gate metal layer 06, an interlayer insulating layer 07, a second buffer layer 08, an active layer (not shown), a first source/drain metal layer (not shown), a second source/drain metal layer 09, an anode layer (not shown), etc. which are laminated one on another sequentially on the base substrate 01. The base substrate 01 may include a first polyimide substrate, a first barrier layer, a second polyimide substrate and a second barrier layer laminated one on another sequentially. The first buffer layer 02 may be made of silicon oxide or silicon nitride. The first gate insulating layer 03 may be made of silicon oxide or silicon nitride. The first gate metal layer 04 may be made of Mo. The second gate insulating layer 05 may be made of silicon oxide or silicon nitride. The second gate metal layer 06 may be made of Mo. The interlayer insulating layer 07 may be made of silicon oxide or silicon nitride. The second buffer layer 08 may be made of silicon oxide. The second source/drain metal layer 09 may be a laminated structure of Ti/Al/Ti.

In a specific example, the first gate metal layer 04 may be made of Mo, the second gate insulating layer 05 may be made of silicon nitride, the second gate metal layer 06 may be made of Mo, the interlayer insulating layer 07 may be made of silicon nitride, and the second buffer layer 08 may be made of silicon oxide. The isolation column structure may be formed by using the first gate metal layer 04, the second gate insulating layer 05, the second gate metal layer 06 and the interlayer insulating layer 07.

In a specific example, the inorganic insulation pattern may be arranged at a same layer and made of a same material as the second gate insulating layer 05, and the first metal pattern may be arranged at a same layer and made of a same material as the first gate metal layer 04.

In some embodiments, the first gate insulating layer is located between the base substrate and the isolation columns, the display substrate includes at least two adjacent isolation columns in a direction parallel to the base substrate, an isolation groove structure is formed between the adjacent isolation columns, and the first gate insulating layer is exposed in the isolation groove structure.

With regard to a film layer on a side of the second buffer layer 08 away from the base substrate, while forming the pattern of the film layer on the side of the second buffer layer 08 away from the base substrate in the display region through a patterning process, the film layer on the side of the second buffer layer 08 away from the base substrate in the transition region may be removed through a same patterning process. For example, the active layer in the transition region is removed through a same patterning process as forming the pattern of the active layer in the display region, the first source/drain metal layer in the transition region is removed through a same patterning process as forming the pattern of the first source/drain metal layer in the display region, the second source/drain metal layer in the transition region is removed through a same patterning process as forming the pattern of the second source/drain metal layer of the display region, the anode layer in the transition region is removed through a same patterning process as forming the pattern of the anode layer in the display region, and a structure shown in FIG. 4 is formed.

In this embodiment, the film layer on the side of the second buffer layer 08 away from the base substrate in the transition region may also be removed through a separate etching process, or the film layer on the side of the second buffer layer 08 in the transition region away from the base substrate may be removed by using an etching solution of the anode layer while forming the pattern of the anode layer in the display region.

As shown in FIG. 4, after the film layer on the side of the second buffer layer 08 away from the base substrate in the transition region is removed, a pattern of a photoresist 10 is formed on the second buffer layer 08, and with the pattern of the photoresist 10 as a mask, dry etching is performed on the first gate metal layer 04, the second gate insulating layer 05, the second gate metal layer 06, the interlayer insulating layer 07 and the second buffer layer 08, to form a structure as shown in FIG. 5. When performing dry etching, an etching gas, an etching pressure and an etching power are firstly adjusted, and the second buffer layer 08 is etched, so as to expose the interlayer insulating layer 07. When performing dry etching on the first gate metal layer 04, the second gate insulating layer 05, the second gate metal layer 06 and the interlayer insulating layer 07, through adjusting an etching gas, an etching pressure and an etching power, an etching rate of the first gate metal layer 04 and the second gate metal layer 06 can be made greater than an etching rate of the second gate insulating layer 05 and the interlayer insulating layer 07, so as to form a structure as shown in FIG. 5. A pattern 25 of the first gate metal layer (namely, the above-mentioned first metal pattern) and a pattern 26 of the second gate insulating layer (namely, the above-mentioned inorganic insulation pattern) form a second isolation column 22, and the pattern 25 of the first gate metal layer is indented with respect to the pattern 26 of the second gate insulating layer, so as to form a recessed portion of the second isolation column 22. A pattern 24 of the second gate metal layer (i.e., the above-mentioned first metal pattern) and a pattern 23 of the interlayer insulating layer (i.e., the above-mentioned inorganic insulation pattern) form a first isolation column 21, and the pattern 24 of the second gate metal layer is indented with respect to the pattern 23 of the interlayer insulating layer, so as to form a recessed portion of the first isolation column 21. In this embodiment, the first gate metal layer 04, the second gate insulating layer 05, the second gate metal layer 06 and the interlayer insulating layer 07 form an isolation column structure, and a height of the isolation column structure can be made to be 0.6 μm-10 μm, so it is able to ensure that the light-emitting layer is interrupted by the isolation column structure. In addition, through adjusting the etching gas, the etching pressure and the etching power, it is able to adjust the etching rate of the first gate metal layer 04 and the second gate metal layer 06 and the etching rate of the second gate insulating layer 05 and the interlayer insulating layer 07, so that a width of the recessed portion in the radial direction of the isolation column is 0.3 μm-1.5 μm, thereby to ensure that the light-emitting layer is interrupted by the isolation column structure.

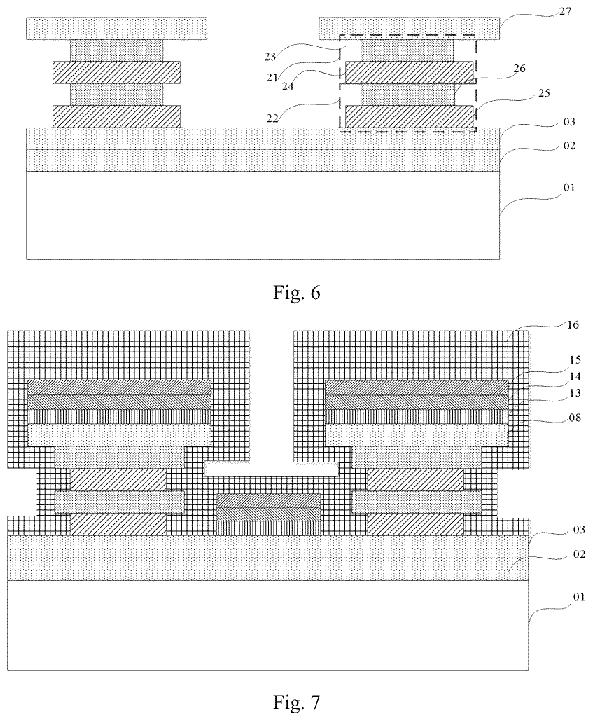

In another specific example, when performing dry etching on the first gate metal layer 04, the second gate insulating layer 05, the second gate metal layer 06 and the interlayer insulating layer 07, through adjusting the etching gas, the etching pressure and the etching power, the etching rate of the first gate metal layer 04 and the second gate metal layer 06 can be made less than the etching rate of the second gate insulating layer 05 and the interlayer insulating layer 07, so as to form a structure as shown in FIG. 6. A pattern 25 of the first gate metal layer (namely, the above-mentioned first metal pattern) and a pattern 26 of the second gate insulating layer (namely, the above-mentioned inorganic insulation pattern) form a second isolation column 22, and the pattern 26 of the second gate insulating layer is indented with respect to the pattern 25 of the first gate metal layer, so as to form a recessed portion of the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 23 of the interlayer insulating layer is indented with respect to the pattern 24 of the second gate metal layer, so as to form a recessed portion of the first isolation column 21. In this embodiment, the first gate metal layer 04, the second gate insulating layer 05, the second gate metal layer 06 and the interlayer insulating layer 07 form an isolation column structure, and a height of the isolation column structure can be made to be 0.6 μm-10 μm, so it is able to ensure that the light-emitting layer is interrupted by the isolation column structure. In addition, through adjusting the etching gas, the etching pressure and the etching power, it is able to adjust the etching rate of the first gate metal layer 04 and the second gate metal layer 06 and the etching rate of the second gate insulating layer 05 and the interlayer insulating layer 07, so that a width of the recessed portion in the radial direction of the isolation column is 0.3 μm-1.5 μm, thereby to ensure that the light-emitting layer is interrupted by the isolation column structure.

In the embodiments of the present disclosure, in order to avoid conduction between the light-emitting layer and the isolation layer, the isolation layer includes an insulation pattern. As shown in FIGS. 5 and 6, the isolation layer may be formed by using the second buffer layer 08. The isolation layer is not limited to be formed by using the second buffer layer 08, but may be formed by using any other film layer. When forming patterns of the isolation column and the isolation layer through dry etching, the isolation layer and the isolation column need to have different etching rates, so that the isolation column can be indented with respect to the isolation layer. Therefore, the insulation pattern of the isolation layer and the inorganic insulation pattern of the isolation column need to be made of different materials, for example, the inorganic insulation pattern of the isolation column is made of silicon nitride, and the insulation pattern of the isolation layer may be made of silicon oxide.

As shown in FIG. 7, after the isolation column structure is formed in the transition region, a light-emitting layer 13, a cathode 14, an organic planarization layer 15 and an encapsulation layer 16 are formed sequentially, and the light-emitting layer 13, the cathode 14 and the organic planarization layer 15 are interrupted by the recessed portion of the isolation column structure, so as to interrupt a common light-emitting material layer, thereby to interrupt an intrusion channel of moisture and oxygen, and avoid the occurrence of encapsulation failure.

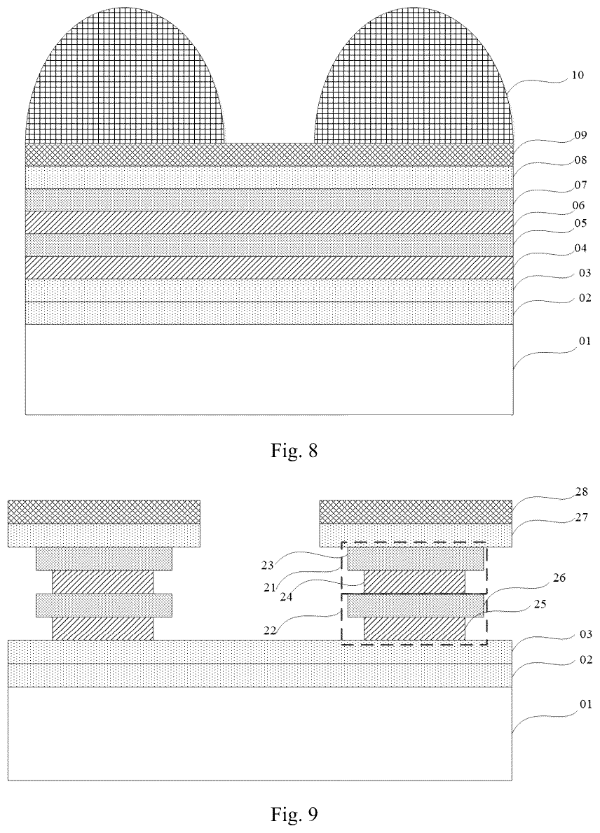

Usually, the insulation pattern of the isolation layer is made of an inorganic insulating material, which has poor toughness and is easy to be fractured. In order to avoid the fracture of the insulation pattern of the isolation layer, a second metal pattern may be provided on a side of the insulation pattern away from the base substrate, the second metal pattern has good toughness and can protect the insulation pattern from being fractured. When the pattern of the isolation column and the pattern of the isolation layer are formed through dry etching, the isolation layer and the isolation column need to have different etching rates, so that the isolation column can be indented relative to the isolation layer. Therefore, the second metal pattern of the isolation layer and the first metal pattern of the isolation column need to be made of different materials, the insulation pattern can be arranged at a same layer and made of a same material as the second buffer layer, and the second metal pattern can be arranged at a same layer and made of a same material as the second source/drain metal layer. In the embodiments of the present disclosure, as shown in FIGS. 8 and 9, the second metal pattern 28 may be formed by using the second source/drain metal layer 09, and an orthogonal projection of the second metal pattern 28 onto the base substrate 01 coincides with an orthogonal projection of the insulation pattern 27 onto the base substrate 01.

As shown in FIG. 8, after the film layer on a side of the second source/drain metal layer 09 away from the base substrate in the transition region is removed, a pattern of a photoresist 10 is formed on the second source/drain metal layer 09, and the pattern of the photoresist 10 is used as a mask to perform dry etching on the first gate metal layer 04, the second gate insulating layer 05, the second gate metal layer 06, the interlayer insulating layer 07, the second buffer layer 08 and the second source/drain metal layer 09, to form a structure as shown in FIG. 9. When performing dry etching, an etching gas, an etching pressure and an etching power are firstly adjusted, and the second buffer layer 08 and the second source/drain metal layer 09 are etched, so as to expose the interlayer insulating layer 07. When performing dry etching on the first gate metal layer 04, the second gate insulating layer 05, the second gate metal layer 06 and the interlayer insulating layer 07, through adjusting an etching gas, an etching pressure and an etching power, the etching rate of the first gate metal layer 04 and the second gate metal layer 06 can be made greater than the etching rate of the second gate insulating layer 05 and the interlayer insulating layer 07, so as to form a structure as shown in FIG. 9. A pattern 25 of the first gate metal layer (namely, the above-mentioned first metal pattern) and a pattern 26 of the second gate insulating layer (namely, the above-mentioned inorganic insulation pattern) form a second isolation column 22 and the pattern 25 of the first gate metal layer is indented with respect to the pattern 26 of the second gate insulating layer, so as to form a recessed portion of the second isolation column 22. A pattern 24 of the second gate metal layer (i.e. the above-mentioned first metal pattern) and the pattern 23 of the interlayer insulating layer (i.e. the above-mentioned inorganic insulation pattern) form a first isolation column 21, and the pattern 24 of the second gate metal layer is indented with respect to the pattern 23 of the interlayer insulating layer, so as to form a recessed portion of the first isolation column 21. In this embodiment, the first gate metal layer 04, the second gate insulating layer 05, the second gate metal layer 06 and the interlayer insulating layer 07 form an isolation column structure, so that a height of the isolation column structure can reach 0.6 μm-10 μm, thereby to ensure that the light-emitting layer is interrupted by the isolation column structure. In addition, through adjusting the etching gas, the etching pressure and the etching power, it is able to adjust the etching rate of the first gate metal layer 04 and the second gate metal layer 06 and the etching rate of the second gate insulating layer 05 and the interlayer insulating layer 07, so that a width of the recessed portion in the radial direction of the isolation column reaches 0.3 μm-1.5 μm, thereby to ensure that the light-emitting layer is interrupted by the isolation column structure.

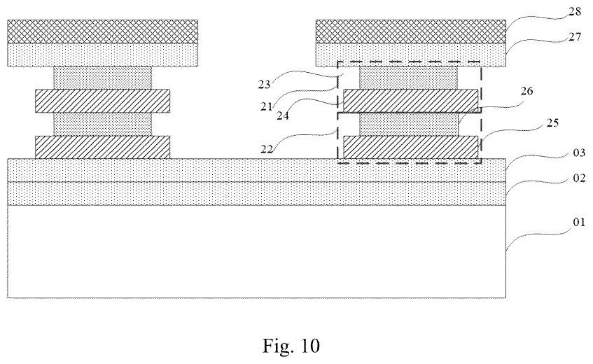

In another specific example, when performing dry etching on the first gate metal layer 04, the second gate insulating layer 05, the second gate metal layer 06 and the interlayer insulating layer 07, through adjusting the etching gas, the etching pressure and the etching power, the etching rate of the first gate metal layer 04 and the second gate metal layer 06 can be made less than the etching rate of the second gate insulating layer 05 and the interlayer insulating layer 07, so as to form a structure as shown in FIG. 10. A pattern 25 of the first gate metal layer (namely, the above-mentioned first metal pattern) and a pattern 26 of the second gate insulating layer (namely, the above-mentioned inorganic insulation pattern) form a second isolation column 22, and the pattern 26 of the second gate insulating layer is indented with respect to the pattern 25 of the first gate metal layer, so as to form a recessed portion of the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 23 of the interlayer insulating layer is indented with respect to the pattern 24 of the second gate metal layer, so as to form a recessed portion of the first isolation column 21. In this embodiment, the first gate metal layer 04, the second gate insulating layer 05, the second gate metal layer 06 and the interlayer insulating layer 07 form an isolation column structure, so that a height of the isolation column structure can reach 0.6 μm-10 μm, so it is able to ensure that the light-emitting layer is interrupted by the isolation column. In addition, through adjusting the etching gas, the etching pressure and the etching power, it is able to adjust the etching rate of the first gate metal layer 04 and the second gate metal layer 06 and the etching rate of the second gate insulating layer 05 and the interlayer insulating layer 07, so that a width of the recessed portion in the radial direction of the isolation column reaches 0.3 μm-1.5 μm, thereby to ensure that the light-emitting layer is interrupted by the isolation column structure.

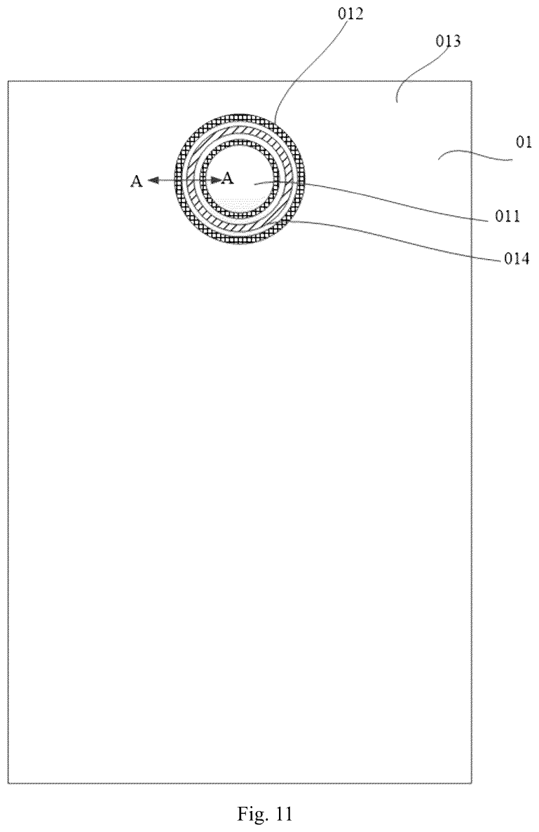

After forming the isolation column structure, when forming the encapsulation layer, a rheological organic material needs to be formed on the display substrate. The rheological organic material is cured to form an organic film layer of the encapsulation layer, the organic film layer needs to be defined in the display region, in a case that the organic film layer is formed in the aperture region, moisture may invade the display region along the organic film layer. Therefore, as shown in FIG. 11, an isolation wall 014 is further provided in the transition region, a height of the isolation wall 014 perpendicular to the base substrate is greater than a height of the isolation column structure 012 perpendicular to the base substrate, so the rheological organic material can be blocked from entering the aperture region via the isolation wall 014.

In some embodiments, the isolation column structure includes: at least one first annular isolation column structure located on one side of the isolation wall away from the aperture region, and at least one second annular isolation column structure located on one side of the isolation wall close to the aperture region. In this way, isolation column structures are provided on both sides of the isolation wall, so as ensure that the light-emitting layer is interrupted at a side of the transition region close to the aperture region, and the light-emitting layer is also interrupted at a side of the transition region close to the display region, thereby to ensure the encapsulation reliability.

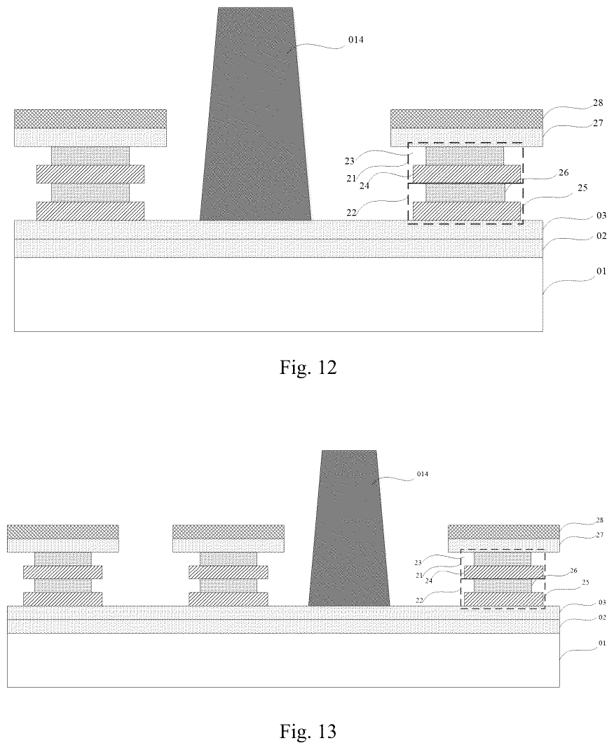

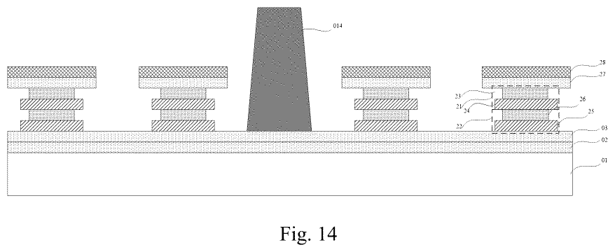

FIG. 12 is a sectional view of the display substrate in FIG. 11 along line AA. As shown in FIG. 12, one annular isolation column structure may be arranged on a side of the isolation wall away from the aperture region, and one annular isolation column structure may be arranged on a side of the isolation wall close to the aperture region. In some embodiments, as shown in FIG. 13, one annular isolation column structure may be provided on one side of the isolation wall away from the aperture region, and two annular isolation column structures may be provided on one side of the isolation wall close to the aperture region. In some embodiments, as shown in FIG. 14, two annular isolation column structures may be provided on the side of the isolation wall away from the aperture region, and two annular isolation column structures may be provided on the side of the isolation wall close to the aperture region.

In the embodiments of present disclosure, the larger the width of the recessed portion in the radial direction of the isolation column is, the more easily the light-emitting layer is interrupted by the recessed portion of the isolation column. However, in the case of an excessive width of the recess portion in the radial direction of the isolation column, the structural strength of the isolation column itself may be adversely affected. In order to ensure that the light-emitting layer is easily interrupted by the undercut structure and to ensure the structural strength of the isolation column itself, the width of the recess portion in the radial direction of the isolation column may be 0.3 μm to 1.5 μm.

In the embodiments of present disclosure, as compared with forming the isolation column by using the source/drain metal layer, multiple film layers are used to form the isolation column structure, so it is able to increase the height of the isolation column structure, where the height of the isolation column structure perpendicular to the base substrate can reach 0.6 μm-10 μm. On one hand, the light-emitting layer can be easily interrupted by the isolation column structure, and on the other hand, a groove-shaped structure can be formed between adjacent isolation column structures in the transition region. Since a depth of the groove-shaped structure is relatively large, after the encapsulation layer is formed, the encapsulation layer can be adhered to, and secured to, a side wall of the groove-shaped structure in a better manner, thereby further to increase the encapsulation reliability.

Embodiments of the present disclosure further provide a method for forming a display substrate, including:
providing a base substrate, the base substrate including an aperture region, a transition region surrounding the aperture region, and a display region surrounding the transition region;
forming at least one annular isolation column structure in the transition region, where the isolation column structure includes a plurality of isolation columns laminated one on another sequentially in a direction away from the base substrate and an isolation layer located at one side of the isolation columns away from the base substrate, the isolation columns surround the aperture region, a recessed portion is formed in a side face of at least one isolation column, at least part of the isolation column is made of an insulating material, orthogonal projections of the isolation columns onto the base substrate are located within an orthogonal projection of the isolation layer onto the base substrate; and
forming a display layer in the transition region and the display region, where the display layer includes a light-emitting layer, and the light-emitting layer is arranged in such a manner as to be interrupted by the recessed portion of the isolation column.

In the related art, a single-layer isolation column is provided and surrounds the aperture region, and a height of the isolation column is limited. In the embodiments of the present disclosure, the isolation column structure includes a plurality of isolation columns laminated one on another sequentially in the direction away from the base substrate, so as to ensure a height of the isolation column structure, thereby to enable the light-emitting layer to be interrupted by the isolation column structure. The isolation column structure further includes an isolation layer, and the isolation layer and the isolation column form an undercut structure, so as to further ensure that the light-emitting layer is interrupted by the isolation column structure. In addition, at least part of the isolation column is made of an insulating material, and the insulating material is non-conductive, so as to avoid conduction between the isolation columns and the light-emitting layer, thereby ensuring that the encapsulation at the isolation column structure does not fail, and improving the encapsulation reliability and product yield of the display substrate.

One annular isolation column structure 012 may be provided in the transition region, alternatively, two or more annular isolation column structures 012 may be provided. As shown in FIG. 1, in a specific example, two annular isolation column structures 012 are provided in the transition region. As shown in FIG. 2, in another specific example, three annular isolation column structures 012 are provided in the transition region. When multiple annular isolation column structures 012 are provided, it facilitates improving the encapsulation effect of the display substrate.

In some embodiments, the display substrate includes a first film layer and a second film layer laminated sequentially in the direction away from the base substrate, and the forming the isolation columns includes:
performing dry etching on the first film layer and the second film layer, to form a first pattern by using the first film layer, and form a second pattern by using the second film layer, an outer edge of the second pattern extending beyond a side wall of the first pattern to form the recessed portion.

In this embodiment, two film layers are used to form the isolation column, it is able to ensure that the isolation column has a sufficient height, thereby to ensure that the light-emitting layer is interrupted by the isolation columns. One of the first film layer and the second film layer may be an inorganic insulating film layer, and the other thereof is a metal film layer, so that the first pattern is an inorganic insulation pattern and the second pattern is a first metal pattern, alternatively, the second pattern is an inorganic insulation pattern, and the first pattern is a first metal pattern. Hence, it is able to avoid conduction between the isolation column and the light-emitting layer through the inorganic insulation pattern, so as to ensure that the encapsulation at the isolation column structure does not fail, thereby improving the encapsulation reliability and product yield of the display substrate.

In some embodiments, forming the isolation column structure includes: forming a first isolation column and a second isolation column laminated sequentially, where an orthogonal projection of the first isolation column onto the base substrate is located within an orthogonal projection of the second isolation column onto the base substrate. In this way, an undercut structure can be formed by the first isolation column and the second isolation column, ensuring that the light-emitting layer is interrupted by the isolation column structure. That the isolation column structure including only two isolation columns is not limited in this embodiment, and the isolation column structure may further include more isolation columns arranged in a laminated manner, so as to provide a higher isolation column structure, thereby ensuring that the light-emitting layer is interrupted by the isolation column structure.

FIGS. 3-10 are sectional views of the display substrate in FIG. 1 along line AA. As shown in FIG. 3, the display substrate includes a first buffer layer 02, a first gate insulating layer 03, a first gate metal layer 04, a second gate insulating layer 05, a second gate metal layer 06, an interlayer insulating layer 07, a second buffer layer 08, an active layer (not shown), a first source/drain metal layer (not shown), a second source/drain metal layer 09, an anode layer (not shown), etc. which are laminated one on another sequentially on the base substrate 01. The base substrate 01 may include a first polyimide substrate, a first barrier layer, a second polyimide substrate and a second barrier layer laminated one on another sequentially. The first buffer layer 02 may be made of silicon oxide or silicon nitride. The first gate insulating layer 03 may be made of silicon oxide or silicon nitride. The first gate metal layer 04 may be made of Mo. The second gate insulating layer 05 may be made of silicon oxide or silicon nitride. The second gate metal layer 06 may be made of Mo. The interlayer insulating layer 07 may be made of silicon oxide or silicon nitride. The second buffer layer 08 may be made of silicon oxide. The second source/drain metal layer 09 may has a laminated structure of Ti/Al/Ti.

In a specific example, the first gate metal layer 04 may be made of Mo, the second gate insulating layer 05 may be made of silicon nitride, the second gate metal layer 06 may be made of Mo, the interlayer insulating layer 07 may be made of silicon nitride, and the second buffer layer 08 may be made of silicon oxide. The isolation column structure may be formed by using the first gate metal layer 04, the second gate insulating layer 05, the second gate metal layer 06 and the interlayer insulating layer 07.

Specifically, forming the isolation column structure includes the following steps.

Step 1, as shown in FIG. 3, a first buffer layer 02, a first gate insulating layer 03, a first gate metal layer 04, a second gate insulating layer 05, a second gate metal layer 06, an interlayer insulating layer 07, a second buffer layer 08, an active layer (not shown), a first source/drain metal layer (not shown), a second source/drain metal layer 09 and an anode layer (not shown) are formed sequentially on a base substrate 01.

The base substrate 01 may include a first polyimide substrate, a first barrier layer, a second polyimide substrate and a second barrier layer laminated one on another sequentially. The first buffer layer 02 may be made of silicon oxide or silicon nitride. The first gate insulating layer 03 may be made of silicon oxide or silicon nitride. The first gate metal layer 04 may be made of Mo. The second gate insulating layer 05 may be made of silicon nitride. The second gate metal layer 06 may be made of Mo. The interlayer insulating layer 07 may be made of silicon nitride. The second buffer layer 08 may be made of silicon oxide. The second source/drain metal layer 09 may has a laminated structure of Ti/Al/Ti.

Step 2, as shown in FIG. 4, the film layer on the side of the second buffer layer 08 away from the base substrate in the transition region is removed.

When the pattern of the film layer on the side of the second buffer layer 08 away from the base substrate in the display region is formed through a patterning process, the film layer on the side of the second buffer layer 08 away from the base substrate in the transition region may be removed through a same patterning process. For example, the active layer in the transition region is removed through a same patterning process as forming the pattern of the active layer in the display region, the first source/drain metal layer in the transition region is removed through a same patterning process as forming the pattern of the first source/drain metal layer in the display region, the second source/drain metal layer in the transition region is removed through a same patterning process as forming the pattern of the second source/drain metal layer of the display region, the anode layer in the transition region is removed through a same patterning process as forming the pattern of the anode layer in the display region, and a structure shown in FIG. 4 is formed.

The film layer on the side of the second buffer layer 08 away from the base substrate in the transition region may also be removed through a separate etching process, or the film layer on the side of the second buffer layer 08 in the transition region away from the base substrate may be removed by using an etching solution of the anode layer while forming the pattern of the anode layer in the display region.

Step 3, as shown in FIG. 4, a pattern of a photoresist 10 is formed on the second buffer layer 08.

Step 4, as shown in FIG. 5, the pattern of the photoresist 10 is used as a mask, dry etching is performed on the first gate metal layer 04, the second gate insulating layer 05, the second gate metal layer 06, the interlayer insulating layer 07 and the second buffer layer 08, to form an isolation column structure.

When performing dry etching, an etching gas, an etching pressure and an etching power are firstly adjusted, the second buffer layer 08 is etched, so as to expose the interlayer insulating layer 07. Specifically, the etching gas may be CF₄ and O₂, a flow rate of CF₄ ranges from 710 sccm (milliliter per minute) to 730 sccm, specifically can be 720 sccm, and a flow rate of O₂ ranges from 470 sccm to 490 sccm, specifically can be 480 sccm. The etching pressure may range from 9 mT to 11 mT, and specifically can be 10 mT (milliTorr). The etching power may range from 17000 W to 19000 W (watts), and specifically may be 18000 W.

Next, dry etching is performed on the first gate metal layer 04, the second gate insulating layer 05, the second gate metal layer 06 and the interlayer insulating layer 07. When performing dry etching on the first gate metal layer 04, the second gate insulating layer 05, the second gate metal layer 06 and the interlayer insulating layer 07, through adjusting the etching gas, the etching pressure and the etching power, the etching rate of the first gate metal layer 04 and the second gate metal layer 06 can be made greater than the etching rate of the second gate insulating layer 05 and the interlayer insulating layer 07, so as to form a structure as shown in FIG. 5. A pattern 25 of the first gate metal layer (i.e., the above-mentioned first metal pattern) and a pattern 26 of the second gate insulating layer (i.e., the above-mentioned inorganic insulation pattern) form a second isolation column 22, and the pattern 25 of the first gate metal layer is indented with respect to the pattern 26 of the second gate insulating layer, so as to form a recessed portion of the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 24 of the second gate metal layer is indented with respect to the pattern 23 of the interlayer insulating layer, so as to form a recessed portion of the first isolation column 21. Specifically, when performing dry etching on the first gate metal layer 04, the second gate insulating layer 05, the second gate metal layer 06 and the interlayer insulating layer 07, the etching gas may be SF₆ and O₂, a flow rate of SF₆ ranges from 800 sccm (milliliter per minute) to 1000 sccm, specifically can be 900 sccm, and a flow rate of O₂ ranges from 800 sccm to 1000 sccm, and specifically can be 900 sccm. The etching pressure may range from 19 mT to 21 mT, and specifically can be 20 mT (milliTorr). The etching power may range from 18000 W (watts) to 20000 W, and specifically may be 19000 W.

In addition, a structure as shown in FIG. 6 may also be formed by adjusting the etching gas, etching pressure and etching power so that the etching rate to the first gate metal layer 04 and the second gate metal layer 06 is less than the etching rate to the second gate insulating layer 05 and the interlayer insulating layer 07. A pattern 25 of the first gate metal layer (i.e., the above-mentioned first metal pattern) and a pattern 26 of the second gate insulating layer (i.e., the above-mentioned inorganic insulation pattern) form a second isolation column 22, and the pattern 26 of the second gate insulating layer is indented with respect to the pattern 25 of the first gate metal layer, so as to form the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 23 of the interlayer insulating layer is indented with respect to the pattern 24 of the second gate metal layer, so as to form a recessed portion of the first isolation column 21.

Step 5, as shown in FIG. 7, a light-emitting layer 13, a cathode 14, an organic planarization layer 15 and an encapsulation layer 16 are formed sequentially, and the light-emitting layer 13, the cathode 14 and the organic planarization layer 15 are interrupted by the recessed portion of the isolation column structure, so as to realize the blocking effect on the common light-emitting material layer, thereby to interrupt an intrusion channel of moisture and oxygen, and avoid the occurrence of encapsulation failure.

In some embodiments, the forming the isolation column structure further includes: forming an isolation layer on one side of the isolation columns away from the base substrate, and orthogonal projections of the isolation columns onto the base substrate are within an orthogonal projection of the isolation layer onto the base substrate. The isolation layer and the isolation columns form an undercut structure, so as further ensure that the light-emitting layer is interrupted by the isolation column structure.

In the embodiments of the present disclosure, in order to avoid conduction between the light-emitting layer and the isolation layer, the isolation layer includes an insulation pattern. As shown in FIGS. 5 and 6, the isolation layer may be formed by using the second buffer layer 08. The isolation layer is not limited to be formed by using the second buffer layer 08, but may be formed by using any other film layer. When forming patterns of the isolation column and the isolation layer through dry etching, the isolation layer and the isolation column need to have different etching rates, so that the isolation column can be indented with respect to the isolation layer. Therefore, the insulation pattern of the isolation layer and the inorganic insulation pattern of the isolation column need to be made of different materials, for example, the inorganic insulation pattern of the isolation column is made of silicon nitride, and the insulation pattern of the isolation layer may be made of silicon oxide.

Usually, the insulation pattern of the isolation layer is made of an inorganic insulating material, which has poor toughness and is easy to be fractured. In order to avoid the fracture of the insulation pattern of the isolation layer, a second metal pattern may be provided on the side of the insulation pattern away from the base substrate, the second metal pattern has good toughness and can protect the insulation pattern from being fractured. When the isolation column and the pattern of the isolation layer are patterned through dry etching, the isolation layer and the isolation column need to have different etching rates, so that the isolation column can be indented relative to the isolation layer. Therefore, the second metal pattern of the isolation layer and the first metal pattern of the isolation column need to be made of different materials. In the embodiments of the present disclosure, as shown in FIGS. 8 and 9, the second metal pattern 28 may be formed by using the second source/drain metal layer 09, and an orthogonal projection of the second metal pattern 28 onto the base substrate 01 coincides with an orthogonal projection of the insulation pattern 27 onto the base substrate 01.

Specifically, forming the isolation column structure includes the following steps.

Step 1, as shown in FIG. 3, a first buffer layer 02, a first gate insulating layer 03, a first gate metal layer 04, a second gate insulating layer 05, a second gate metal layer 06, an interlayer insulating layer 07, a second buffer layer 08, an active layer (not shown), a first source/drain metal layer (not shown), a second source/drain metal layer 09 and an anode layer (not shown) are formed sequentially on a base substrate 01.

The base substrate 01 may include a first polyimide substrate, a first barrier layer, a second polyimide substrate and a second barrier layer laminated one on another sequentially. The first buffer layer 02 may be made of silicon oxide or silicon nitride. The first gate insulating layer 03 may be made of silicon oxide or silicon nitride. The first gate metal layer 04 may be made of Mo. The second gate insulating layer 05 may be made of silicon nitride. The second gate metal layer 06 may be made of Mo. The interlayer insulating layer 07 may be made of silicon nitride. The second buffer layer 08 may be made of silicon oxide. The second source/drain metal layer 09 may has a laminated structure of Ti/Al/Ti.

Step 2, as shown in FIG. 8, the film layers such as the active layer, the first source/drain metal layer and the anode layer in the transition region are removed, and the first buffer layer 02, the first gate insulating layer 03, the first gate metal layer 04, the second gate insulating layer 05, the second gate metal layer 06, the interlayer insulating layer 07, the second buffer layer 08 and the second source/drain metal layer 09 in the transition region are remained.

When the pattern of the film layer on the side of the second buffer layer 08 away from the base substrate in the display region is formed through a patterning process, the film layer on the side of the second buffer layer 08 away from the base substrate in the transition region may be removed through a same patterning process. For example, the active layer in the transition region is removed through a same patterning process as forming the pattern of the active layer in the display region, the first source/drain metal layer in the transition region is removed through a same patterning process as forming the pattern of the first source/drain metal layer in the display region, the anode layer in the transition region is removed through a same patterning process as forming the pattern of the anode layer in the display region, and a structure shown in FIG. 8 is formed.

Step 3, as shown in FIG. 8, a pattern of a photoresist 10 is formed on the second source/drain metal layer 09.

Step 4, as shown in FIG. 9, the pattern of the photoresist 10 is used as a mask, dry etching is performed on the first gate metal layer 04, the second gate insulating layer 05, the second gate metal layer 06, the interlayer insulating layer 07, the second buffer layer 08 and the second source/drain metal layer 09, to form an isolation column structure.

When performing dry etching, an etching gas, an etching pressure and an etching power are firstly adjusted, the second source/drain metal layer 09 and the second buffer layer 08 are etched, so as to expose the interlayer insulating layer 07. Specifically, the etching gas may be CF₄ and O₂, a flow rate of CF₄ ranges from 710 sccm (milliliter per minute) to 730 sccm, specifically can be 720 sccm, and a flow rate of O₂ ranges from 470 sccm to 490 sccm, specifically can be 480 sccm. The etching pressure may range from 9 mT to 11 mT, and specifically can be 10 mT (milliTorr). The etching power may range from 17000 W to 19000 W (watts), and specifically may be 18000 W.

Next, dry etching is performed on the first gate metal layer 04, the second gate insulating layer 05, the second gate metal layer 06 and the interlayer insulating layer 07. When performing dry etching on the first gate metal layer 04, the second gate insulating layer 05, the second gate metal layer 06 and the interlayer insulating layer 07, through adjusting the etching gas, the etching pressure and the etching power, the etching rate of the first gate metal layer 04 and the second gate metal layer 06 can be made greater than the etching rate of the second gate insulating layer 05 and the interlayer insulating layer 07, so as to form a structure as shown in FIG. 9. A pattern 25 of the first gate metal layer (i.e., the above-mentioned first metal pattern) and a pattern 26 of the second gate insulating layer (i.e., the above-mentioned inorganic insulation pattern) form a second isolation column 22, and the pattern 25 of the first gate metal layer is indented with respect to the pattern 26 of the second gate insulating layer, so as to form a recessed portion of the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 24 of the second gate metal layer is indented with respect to the pattern 23 of the interlayer insulating layer, so as to form a recessed portion of the first isolation column 21. Specifically, when performing dry etching on the first gate metal layer 04, the second gate insulating layer 05, the second gate metal layer 06 and the interlayer insulating layer 07, the etching gas may be SF₆ and O₂, a flow rate of SF₆ ranges from 800 sccm (milliliter per minute) to 1000 sccm, and specifically can be 900 sccm, and a flow rate of O₂ ranges from 800 sccm to 1000 sccm, specifically can be 900 sccm. The etching pressure may range from 19 mT to 21 mT, and specifically can be 20 mT (milliTorr). The etching power may range from 18000 W (watts) to 20000 W, and specifically may be 19000 W.

In addition, a structure as shown in FIG. 10 may also be formed by adjusting the etching gas, etching pressure and etching power so that the etching rate to the first gate metal layer 04 and the second gate metal layer 06 is less than the etching rate to the second gate insulating layer 05 and the interlayer insulating layer 07. A pattern 25 of the first gate metal layer (i.e., the above-mentioned first metal pattern) and a pattern 26 of the second gate insulating layer (i.e., the above-mentioned inorganic insulation pattern) form a second isolation column 22, and the pattern 26 of the second gate insulating layer is indented with respect to the pattern 25 of the first gate metal layer, so as to form the second isolation column 22. A pattern 24 of the second gate metal layer (namely, the above-mentioned first metal pattern) and a pattern 23 of the interlayer insulating layer (namely, the above-mentioned inorganic insulation pattern) form a first isolation column 21, and the pattern 23 of the interlayer insulating layer is indented with respect to the pattern 24 of the second gate metal layer, so as to form a recessed portion of the first isolation column 21.

Next, a light-emitting layer 13, a cathode 14, an organic planarization layer 15 and an encapsulation layer 16 may be formed sequentially on the structure shown in FIG. 9, and the light-emitting layer 13, the cathode 14 and the organic planarization layer 15 are interrupted by the recessed portion of the isolation column structure, so as to realize the blocking effect on the common light-emitting material layer, thereby to interrupt an intrusion channel of moisture and oxygen, and avoid the occurrence of encapsulation failure.

After forming the isolation column structure, when forming the encapsulation layer, a rheological organic material needs to be formed on the display substrate. The rheological organic material is cured to form an organic film layer of the encapsulation layer, the organic film layer needs to be defined in the display region, in a case that the organic film layer is formed in the aperture region, moisture may the display region along the organic film layer. Therefore, the method further includes: forming an isolation wall in the transition region, where a height of the isolation wall perpendicular to the base substrate is greater than a height of the isolation column structure perpendicular to the base substrate. Thus, the rheological organic material can be blocked from entering the aperture region via the isolation wall 014.

The isolation column structures may be provided on both sides of the isolation wall, so as ensure that the light-emitting layer is interrupted at the side of the transition region close to the aperture region, and the light-emitting layer is also interrupted at the side of the transition region close to the display region, thereby to ensure the encapsulation reliability.

FIG. 12 is a sectional view of the display substrate in FIG. 11 along line AA. As shown in FIG. 12, one annular isolation column structure may be arranged on a side of the isolation wall away from the aperture region, and one annular isolation column structure may be arranged on a side of the isolation wall close to the aperture region. In some embodiments, as shown in FIG. 13, one annular isolation column structure may be provided on one side of the isolation wall away from the aperture region, and two annular isolation column structures may be provided on one side of the isolation wall close to the aperture region. In some embodiments, as shown in FIG. 14, two annular isolation column structures may be provided on the side of the isolation wall away from the aperture region, and two annular isolation column structures may be provided on the side of the isolation wall close to the aperture region.

In the embodiments of the present disclosure, the order of the steps is not limited to the serial numbers thereof. For a person skilled in the art, any change in the order of the steps shall also fall within the scope of the present disclosure if without any creative effort.

It should be noted that the display substrate proposed in the embodiments of the present disclosure is not limited to the specific structure formed by using the method in the above-mentioned embodiments of the present disclosure, and under the concept of the present disclosure, the specific structure of the display substrate may also be formed by a person skilled in the art through other processing techniques.

Another embodiment of the present application provides a display device including the above-mentioned display substrate. The display device may be any product or member with a display function, such as electronic paper, a mobile phone, a tablet computer, a television, a display, a notebook computer, a digital photo frame and a navigator. A sensing device, e.g., a camera, a fingerprint identification device, an infrared sensor, an identification sensor, a pressure sensor and any other sensing device that is applicable to the display device, is provided in the aperture region, which is not particularly defined herein.

It should be further appreciated that, the above embodiments have been described in a progressive manner, and the same or similar contents in the embodiments have not been repeated, i.e., each embodiment has merely focused on the difference from the others. Especially, the product embodiments are substantially similar to the method embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The aforementioned are merely specific embodiments of the present disclosure, but a scope of the present disclosure is not limited thereto. Any modifications or replacements that would easily occurred to a person skilled in the art, without departing from the technical scope disclosed in the disclosure, should be encompassed in the scope of the present disclosure. Therefore, the scope of the present disclosure shall be subject to the scope defined by the appended claims.

1. A display substrate, comprising:
a base substrate, comprising an aperture region, a transition region surrounding the aperture region, and a display region surrounding the transition region;
at least one annular isolation column structure in the transition region, wherein the isolation column structure comprises a plurality of isolation columns laminated one on another sequentially in a direction away from the base substrate and an isolation layer located at one side of the isolation columns away from the base substrate, the isolation columns surround the aperture region, a recessed portion is formed in a side face of at least one isolation column, at least part of the isolation column is made of an insulating material, orthogonal projections of the isolation columns onto the base substrate are located within an orthogonal projection of the isolation layer onto the base substrate; and
a display layer, covering the transition region and the display region, wherein the display layer comprises a light-emitting layer, and the light-emitting layer is arranged in such a manner as to be interrupted by the recessed portion of the isolation column.

2. The display substrate according to claim 1, wherein the isolation column comprises: a first pattern and a second pattern laminated sequentially in the direction away from the base substrate, an outer edge of the second pattern extending beyond a side wall of the first pattern to form the recessed portion.

3. The display substrate according to claim 1, wherein the isolation column structure comprises a first isolation column and a second isolation column laminated sequentially in the direction away from the base substrate, an orthogonal projection of the first isolation column onto the base substrate is located within an orthogonal projection of the second isolation column onto the base substrate, the first isolation column and the second isolation column each comprises a first pattern and a second pattern laminated sequentially in the direction away from the base substrate, and an outer edge of the second pattern extends beyond a side wall of the first pattern to form the recessed portion.

4. The display substrate according to claim 2, wherein
the first pattern is an inorganic insulation pattern, and the second pattern is a first metal pattern; or
the second pattern is an inorganic insulation pattern, and the first pattern is a first metal pattern.

5. The display substrate according to claim 4, wherein the display substrate at least comprises a first buffer layer, a first gate insulating layer, a first gate metal layer, a second gate insulating layer, a second gate metal layer, an interlayer insulating layer, a second buffer layer and a second source/drain metal layer laminated one on another sequentially on the base substrate; and
the inorganic insulation pattern is arranged at a same layer and made of a same material as the second gate insulating layer, and the first metal pattern is arranged at a same layer and made of a same material as the first gate metal layer.

6. The display substrate according to claim 5, wherein the isolation layer comprises an insulation pattern and/or a second metal pattern, and the isolation layer and the isolation column are made of different materials.

7. The display substrate according to claim 6, wherein the insulation pattern is arranged at a same layer and made of a same material as the second buffer layer, and the second metal pattern is arranged at a same layer and made of a same material as the second source/drain metal layer.

8. The display substrate according to claim 5, wherein the first gate insulating layer is located between the base substrate and the isolation columns; the display substrate comprises at least two adjacent isolation columns in a direction parallel to the base substrate, an isolation groove structure is formed between the adjacent isolation columns, and the first gate insulating layer is exposed in the isolation groove structure.

9. The display substrate according to claim 5, wherein the first gate insulating layer and the second buffer layer are made of silicon oxide, the first buffer layer, the second gate insulating layer and the interlayer insulating layer are made of silicon nitride, and the first gate metal layer and the second gate metal layer are made of Mo.

10. The display substrate according to claim 1, wherein the display substrate further comprises:
an isolation wall located in the transition region, a height of the isolation wall perpendicular to the base substrate being greater than a height of the isolation column structure perpendicular to the base substrate; and
wherein the isolation column structure comprises:
at least one first annular isolation column structure located on one side of the isolation wall away from the aperture region; and
at least one second annular isolation column structure located on one side of the isolation wall close to the aperture region.

11. The display substrate according to claim 1, wherein a height of the isolation column structure perpendicular to the base substrate ranges from 0.6 μm to 10 μm.

12. The display substrate according to claim 1, wherein the recessed portion has a width of 0.3 μm to 1.5 μm in a radial direction of the isolation column.

13. A display device, comprising the display substrate according to claim 1.

14. A method for forming a display substrate, comprising:
providing a base substrate, the base substrate comprising an aperture region, a transition region surrounding the aperture region, and a display region surrounding the transition region;
forming at least one annular isolation column structure in the transition region, wherein the isolation column structure comprises a plurality of isolation columns laminated one on another sequentially in a direction away from the base substrate and an isolation layer located at one side of the isolation columns away from the base substrate, the isolation columns surround the aperture region, a recessed portion is formed in a side face of at least one isolation column, at least part of the isolation column is made of an insulating material, orthogonal projections of the isolation columns onto the base substrate are located within an orthogonal projection of the isolation layer onto the base substrate; and
forming a display layer in the transition region and the display region, wherein the display layer comprises a light-emitting layer, and the light-emitting layer is arranged in such a manner as to be interrupted by the recessed portion of the isolation column.

15. The method for forming the display substrate according to claim 14, wherein the display substrate comprises a first film layer and a second film layer laminated sequentially in the direction away from the base substrate, and the forming the isolation columns comprises:
performing dry etching on the first film layer and the second film layer, to form a first pattern by using the first film layer, and form a second pattern by using the second film layer, wherein an outer edge of the second pattern extends beyond a side wall of the first pattern to form the recessed portion.

16. The display device according to claim 13, wherein the isolation column comprises:
a first pattern and a second pattern laminated sequentially in the direction away from the base substrate, an outer edge of the second pattern extending beyond a side wall of the first pattern to form the recessed portion.

17. The display device according to claim 13, wherein the isolation column structure comprises a first isolation column and a second isolation column laminated sequentially in the direction away from the base substrate, an orthogonal projection of the first isolation column onto the base substrate is located within an orthogonal projection of the second isolation column onto the base substrate, the first isolation column and the second isolation column each comprises a first pattern and a second pattern laminated sequentially in the direction away from the base substrate, and an outer edge of the second pattern extends beyond a side wall of the first pattern to form the recessed portion.

18. The display device according to claim 16, wherein
the first pattern is an inorganic insulation pattern, and the second pattern is a first metal pattern; or
the second pattern is an inorganic insulation pattern, and the first pattern is a first metal pattern.

19. The display device according to claim 18, wherein the display substrate at least comprises a first buffer layer, a first gate insulating layer, a first gate metal layer, a second gate insulating layer, a second gate metal layer, an interlayer insulating layer, a second buffer layer and a second source/drain metal layer laminated one on another sequentially on the base substrate; and
the inorganic insulation pattern is arranged at a same layer and made of a same material as the second gate insulating layer, and the first metal pattern is arranged at a same layer and made of a same material as the first gate metal layer.

20. The display device according to claim 19, wherein the isolation layer comprises an insulation pattern and/or a second metal pattern, and the isolation layer and the isolation column are made of different materials.
